(19) United States
(12) Patent Application Publication
(10) Pub. No.: US 2019/0085436 A1
(43) Pub. Date: Mar. 21, 2019

(54) DEVELOPED INTRINSIC TWO-WAY SHAPE MEMORY THIN FILM

(71) Applicants: Mahmoud Nili Ahmadabadi, Tehran (IR); Maryam Mohri, Tehran (IR)

(72) Inventors: Mahmoud Nili Ahmadabadi, Tehran (IR); Maryam Mohri, Tehran (IR)

(21) Appl. No.: 15/707,033

(22) Filed: Sep. 18, 2017

(51) Int. Cl. C22F 1/00; C23C 14/35; C23C 14/58; C23C 14/16; C22F 1/10

(52) U.S. Cl. CPC C22F 1/006; C23C 14/352; F03G 7/065; C23C 14/165; C22F 1/10; C23C 14/5806

(57) ABSTRACT

NiTi thin films with composition gradient have the added feature of an intrinsic two-way shape memory effect. According to the invention, a method of fabrication of Ni-rich/(NiTiCu) Ti-rich bi-layer thin film is disclosed. The bi-layer thin film formed compositional gradients at the interface of the films through diffusion. The bi-layer presented a combined pseudo elastic behavior and shape memory effect with a reduced hysteresis. The combination of pseudo elastic with shape memory effect produces an intrinsic two-way shape memory effect (TWSME). This behavior achieved without needing complicated heat treatment and training process. Therefore, it is compatible with MEMS processing.

### BACKGROUND OF THE INVENTION

Among the materials known as shape memory alloys (SMAs), NiTi-based alloys have received wide attention due to their strong recovery force, large recovery strain and bio-compatibility. In the form of thin films, SMAs are being developed for a variety of applications in micro-electromechanical systems (MEMS). They have been used to fabricate actuator devices, such as micro-pumps, micro-valves and micro-grippers.

Controlling the transformation of NiTi thin films are achieved by changing the composition and microstructure of a single homogeneous layer. In order to successfully develop functionally graded TiNi thin films for MEMS application, it is necessary to characterize and control the variations in composition, thermo-mechanical properties and residual stress in these films. While the potential applications for shape memory alloys (SMAs) in MEMS are large, the difficulties with fabricating quality material and achieving TWSME are preventing widespread use of this actuator material.

Since the early 1990s, several trials have been made in order to fabricate TiNi thin films using a sputter-deposition method. The as-deposited film was shown by XRD to be amorphous and after vacuum annealing at 550° C. for 30 minutes, exhibited the SME. Although the transformation temperatures are 100° C. lower than the target material. The transformation and shape memory characteristics of TiNi thin films were shown to depend strongly on metallurgical factors and sputtering conditions, Ishida et al and Kajiwara et al. In order to improve the response, it is necessary to decrease the temperature hysteresis. Addition of Cu is effective in decreasing the transformation temperature hysteresis without decreasing transformation temperatures themselves. TiNiCu thin films with Cu-contents varying from 0 to 18% were investigated, Miyazaki et al and Meng et al. The achievement of the small transformation temperature hysteresis in NiTiCu thin films is promising for achieving quick movement in micro actuators made of NiTi shape memory thin films.

Thin film NiTi actuators are well suited for MEMS devices because of their large work energy densities. However, the difficulties associated with depositing this material have limited its access by the MEMS community. To address, researchers focused on deposition, heat treatments, and thermo-mechanical characterization of the film. Few researchers developed actual micro devices. While the potential applications for SMA MEMS are large, the difficulties with fabricating quality material and achieving the two-way effect are preventing widespread use of this actuator material. NiTi films with transformation temperatures above room temperature are difficult to manufacture.

Sputtering directly from a 50/50 atm % NiTi target results in films with dramatically lowered transformation temperature, prohibiting its use as an actuator. This is caused by the fact that NiTi alloys are strongly dependent on the composition, annealing temperatures, aging time and sputtering parameters, Wolf et al. Of these factors, alloy composition is the most critical.

The most critical consideration in making a shape memory alloy, whether in bulk or in thin film, is chemical composition. NiTi alloys are strongly dependent on the composition, annealing temperatures, aging time and sputtering parameter. Composition is the most critical sputtering parameter. Typically small change in composition occurs during sputtering because titanium readily reacts with other materials. A shift in composition of as little as 1 atm % can alter transformation temperatures by 100° C., Gyobu et al. Titanium is typically used to getter materials, and is often used in vacuum systems to pull down a vacuum by reacting with the gases and condensing. Miyazaki, et al. compensated for the titanium loss by placing titanium plates on top of the alloy target, thereby effectively altering the composition of the target, Miyazaki et al. Wolf et al. similarly compensated with titanium foils, and A. Gyobu et al. sputtered from 50/50 NiTi target using titanium compensation. The other method of compensating for the titanium loss is to use a multi-gun co-sputtering system. For example, Krulevitch et al. used a DC magnetron system to sputter from individually powdered Ni, Ti, and Cu targets.

A further complication is that the NiTi phase is very narrow at low temperatures. Slight shifts in the Ni:Ti stoichiometry can cause precipitate formation, and complicate the metallurgical heat treatment required to establish a desired transformation temperature.

Sputtering of NiTi thin film from a 50/50 atm % NiTi target produces films with transformation temperatures different from the target due to loss of titanium during sputtering. NiTi films with transformation temperatures above room temperature are difficult to manufacture. Sputtering processes typically produce films with reduced transformation temperatures (i.e. below room temperature), requiring artificial cooling to use as an actuator.

Researchers have compensated for this, by placing Ti plates on the target to effectively alter the composition of the target, or to sputter of a nonstoichiometric NiTi target. Functionally graded material (FGM) is a material in which the composition or structure gradually varies, resulting in a variation in material properties (usually in one direction). This perception has been used for various structural and functional applications. In typical FGM plates and thin films, the material composition changes within the thickness of the structure, providing the desired gradient of material properties.

Multilayered or functionally graded NiTi-based films can be tailored to improve the properties of NiTi films. In order to develop graded NiTi thin films for MEMS application, it is essential to study and control the changes in composition, mechanical properties and residual stresses in these thin films. The functional properties of SMAs are often noticed in two distinctive behaviors, known as pseudo elasticity and the shape memory effect, Sun et al. The weak controllability of the shape memory element is a challenge for actuator design. One way to solve this problem is to create functionally graded NiTi components, Miyazaki et al and Winzek et al. In SMAs, functionally graded structures, particularly provides transformation properties gradient through the thickness.

For SMA plates and thin films, several functionally graded designs were performed. One approach was to gradually change the Ni—Ti composition ratio in the thickness direction, Fu et al. Fabrication of thin functionally graded NiTi plates by means of surface laser annealing was reported, Martins et al. Also, compositional graded thin NiTi plates have been created by surface diffusion of Ni through the thickness of equiatomic NiTi plates, Ishida et al.

The other approach is co-sputtered NiTi films from an alloyed and elemental target, applying variable power to the elemental Ti target during deposition and again resulting in a compositional gradient through the film thickness, Cole et al. However, NiTi thin films currently require complex thermo-mechanical training in order to be actuated, which becomes more difficult as devices approach the micro-scale. Most devices that implement SMA films as actuators only permit repeatable actuation behavior by applying a biasing force to a homogeneous film. The two-way shape memory effect is highly desirable in the manufacture of the MEMS. To achieve a cyclical, two-way effect, a biasing force is required to reshape the NiTi when cooled. The fabrication process required complicated heat treatments. The stability of these precipitates can degrade over numerous thermal cycles.

K. H. Ho and et al in 2004 disclosed devices and a method of fabrication of devices using a shape memory effect, thin film with a compositional gradient through he thickness of the film. The process of fabrication included a gradual heating of the target over time during the sputter deposition of a thin film on a substrate under high vacuum, without compositional modification. The resulting thin film two-way shape memory effect that can be cyclically applied without an external bias force.

D. P. Cole in 2009 presented a new method for processing and characterizing compositionally-graded transformable thin films. Single and multilayer graded films were deposited onto bulk NiTi substrates. Annealing the films naturally produced a compositional gradient across the film-substrate interface through diffusion modification.

### SUMMARY OF INVENTION

Ni—Ti thin film shape memory alloys (SMAs) have become a promising material for micro-actuators because of their excellent mechanical properties and biocompatibility. A NiTi bi-layer thin film (Ni-rich/Ti-rich (NiTiCu)) was developed and deposited onto Si substrate by DC magnetron sputter deposition from separate alloy targets. The developed Ni-rich/Ti-rich (NiTiCu) bi-layer thin film exhibits combined pseudo elastic behavior and shape memory effect at the same time similar to the austenitic and martensitic thin films, respectively, with a reduced hysteresis. The variation of chemical composition throughout thin film thickness caused a gradual change in the transformation temperature and also induced stress in the interface of thin film, which consequently showed intrinsic two-way shape memory effect without any required thermo-mechanical treatment.

### BRIEF DESCRIPTION OF DRAWINGS

FIG. 1 illustrates the DSC curve of crystallization temperature of the as-deposited the bi-layer thin film.

FIG. 2 is XRD profile of the bi-layer thin film before and after annealing at 500° C. for 1 h.

FIG. 3 shows DSC curves of the bi-layer after annealing at the 500° C. for 1 h, 1^{st} zone is related to austenitic layer and 2^{nd} zone is related to martensitic layer.

FIG. 4 shows electrical resistivity measurement as a function of temperature for the bi-layer thin film annealed at 500° C. for 1 h.

FIG. 5 is a STEM micrograph of a cross section of (a) the bi-layer after annealing at 500° C. for 1 h, (b) the section close to the substrate in Ni-rich layer, (c) the section close to the interface of the layer and (d) the section of the NiTiCu layer.

FIG. 6 shows the surface morphology of the bi-layer thin film annealed at 500° C. for 1 h.

FIG. 7 is load-displacement curve of the bi-layer.

FIG. 8 shows the load-depth curves of the bi-layer NiTi thin film for three different loading-unloading conditions.

FIGS. 9 (a-c) illustrate schematic of the spherical cavity model for the bi-layer at different loading, (a) 1.5 mN, (b) 5 mN, (c) 10 mN. (M and A indicate martensitic and austenitic structures, respectively)

FIG. 10 shows Cross-section of AFM scans of indentation in the bi-layers before and after heating showing depth recovery. Film annealed at 80° C. for 2 min.

FIGS. 11 (a-c) are a demonstration of the two-way shape memory effect of the bi-layer thin film. The film change spontaneously between (a) room temperature shape, (b) high temperature shape and (c) room temperature shape.

FIG. 12 is schematic of residual stresses and its effect on the two-way shape memory effect in the bi-layer.

### DETAILED DESCRIPTION

The present invention aims to design and prepare a bi-layer thin film with a gradient in chemical composition. Special attention has been paid to the shape memory behavior and super elasticity effect of the bi-layer with different chemical compositions and small thermal hysteresis. In addition, it has been shown the bi-layer NiTi film can be fabricated with an intrinsic two-way shape memory effect without complicated heat treatment and training process that is incompatible with MEMS processing.

The bi-layer thin films; Ni-rich/Ti-rich(NiTiCu) was deposited using DC magnetron sputtering using two alloy targets onto Si (111) substrates. The alloy targets were prepared using vacuum arc re-melting (VAR). Due to the different angular sputtering distributions for Ni and Ti, the film composition deviates from the composition of the target. A typical loss rate of 4-4.5 at % Ti between cast-melted target and sputter deposited film was reported. The films were deposited using the following parameters: base pressures<10⁻⁷ mbar, P_{Ar}≈3×10⁻³ mbar, target substrate distance=50 mm, power=200 W. The substrate holder was kept rotating during deposition in order to achieve a uniform distribution of composition. For making the bi-layer, at the first the Ni-rich layer was deposited onto Si substrate with thickness about 1 μm and then NiTiCu were deposited onto Ni-rich layer. The film thicknesses were determined using a Dektak surface profiller is about 2 μm.

In order to crystallize the as-deposited amorphous film, thin films were annealed at 500° C. for 1 h under vacuum (<10⁻⁷ mbar). Grazing incidence X-ray diffraction measurements of the as-deposited and annealed thin films were carried out at room temperature using a Bruker diffractometer of Cu-K_{α} radiation. The crystallization and transformation temperatures were measured using DSC (NETZSCH DSC 404C) on the thin films after removal from the substrates. Heating and cooling rates were maintained at 10° C./min. Also, a standard four-point electrical resistivity measurement characterized the transformation temperatures.

In general, the films deposited at room temperature were usually amorphous in nature. The amorphous NiTi thin films do not exhibit the shape memory effect, and then an annealing process is necessary to yield the shape memory effect and super elasticity behaviors. Therefore, high temperature deposition or post annealing was required to make them crystalline.

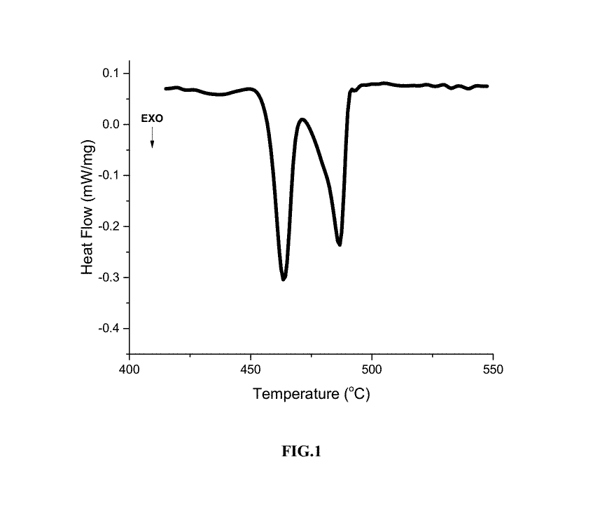

It was suggested that post annealing should be done at the lowest possible annealing temperature for the minimum annealing duration to minimize the reaction between film and substrate otherwise it could lead to dramatic changes in the film microstructure, mechanical properties and shape memory effects. FIG. 1 gives typical continuous heating DSC trace obtained from the bi-layer thin film. As seen in FIG. 1, the heating curve shows distinct exotherms corresponding to the formation of various crystalline phases from its amorphous state.

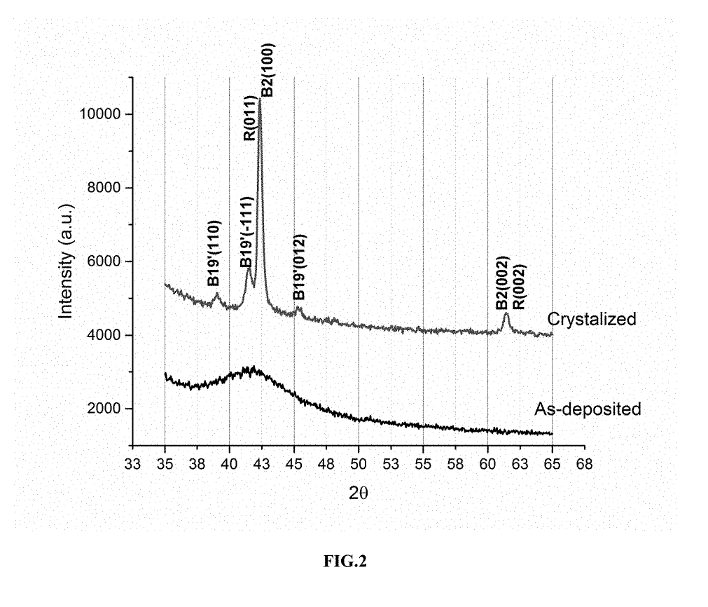

There are two peaks in the heating curve, which related to each layer in the bi-layer. The crystallization temperature peaks are around 463° C. and 487° C. Previous researches have shown a decrease in crystallization temperatures and activation energies with the addition of copper, Chang et al. Therefore, it is assumed that the crystallization temperature of the Cu content layer to be around 463° C. and NiTi Ni-rich layer to be about 487° C. These results show that crystallization curve shows good agreement with the crystallization temperature of conventional sputtered NiTi thin film, Lehnert et al. According to the DSC results, the bi-layer was annealed at 500° C. for 1 h under vacuum (<10⁻⁷ mbar). Room temperature X-ray patterns of the bi-layer thin films before and after annealing are displayed in FIG. 2. The XRD pattern of the as-deposited film only exhibit a broad peak at approx. 2θ=43°, indicating an amorphous structure. Thin film specimen after annealing at 500° C. for 1 h, was completely crystallized. The annealed bi-layer thin film shows the martensitic (B19′), austenite (B2) and R phase (trigonal phase).

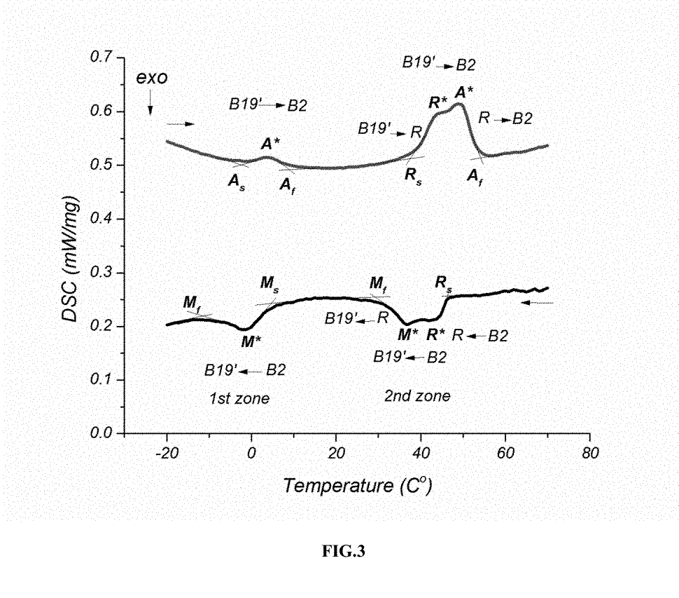

The existence of the martensite peaks at room temperature indicates that the shape memory effect and phase transformation occur above room temperature, as confirmed by DSC and electrical resistivity measurements shown in FIGS. 3 and 4, respectively. Rₛ, R_{f}, Mₛ, M_{f} and Aₛ, A_{f} are the temperatures for the start and finish of formation of the intermediate R-phase and martensite, on cooling, and austenite, on heating.

DSC curves of the bi-layer thin film (FIG. 3) illustrate two transformation zones associated with the each layer transformation during thermal cycling. In the heating curve, the first peak is related to the transformation of martensite to the austenite phase in the Ni-rich layer and the second peak shows multiple-step phase transformation (B19′→R, B19′→B2, R→B2) related to the NiTiCu layer. Reverse transformations occurred in the cooling curve are shown in FIG. 3.

The curves of electrical resistivity-temperature (FIG. 4) show a rough increase of the electrical resistivity related to the R-phase transformation during cooling. Furthermore, FIG. 4 illustrates that there are two-step phase transformation (austenite→R-phase→martensite) in the bi-layer. The first martensite plate formed at Mₛ upon cooling will be the last to disappear at A_{f} upon heating. Thus, the transformation hysteresis is defined by the temperature difference between A_{f} and Mₛ. Similarly, the temperature difference between Aₛ and M_{f} is also taken as transformation hysteresis. The phase transformation temperatures and transformation hysteresis are listed in Table 1.

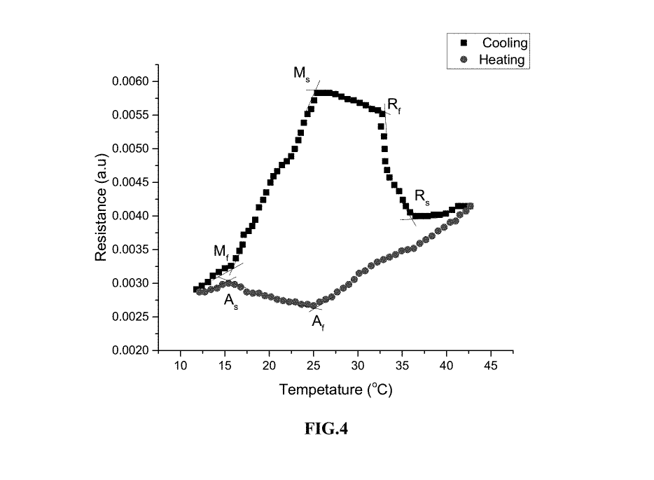

TABLE 1
Transformation temperature and hysteresis width of the bi-layers thin film
corresponding to FIG. 5.

| | T | | | | | | |
|---|---|---|---|---|---|---|---|
| | (° C.) | | | | | | |
| | | | | | | | ΔT = A_{f} − |
| Sample | A_{f} | Aₛ | Mₛ | M_{f} | Rₛ | R_{f} | Mₛ |
| Bi-layer | 25 | 14 | 26 | 16 | 36 | 32 | ≈1 |

Drastic reduction of thermal hysteresis in the bi-layer is likely due to the existence of chemical composition and stress gradients in the bi-layer. The micro structure of the bi-layer was studied using scanning transmission electron microscopy (STEM, Titan 80-300). The Cross section TEM sample was prepared by focused ion beam (Zeiss Auriga 60 Dual Beam FIB). The STEM images of a cross section of the bi-layer (FIG. 5(a-d)) illustrate the presence of the stress gradient in this bi-layer. As depicted in FIG. 5a, the bi-layer thin film was completely crystallized after annealing at 500° C. for 1 h as confirmed by XRD results. Furthermore, there are nano-crystalline grains (30-50 nm) in the top layer (NiTiCu) and lens shaped Ni₄Ti₃ precipitates in the bottom layer (Ni-rich).

These lens-shaped Ni₄Ti₃ precipitates are reported in Ni-rich thin films. Stress can induce preferential growth of selective precipitate variant, as Ni₄Ti₃ precipitates in Ni-rich Ni—Ti. The preferential growth of Ni₄Ti₃ was proposed by Nishida et al. and confirmed by Li and Chen under uniaxial stress condition. Precipitate variant whose habit plane is more parallel to the stress axis is formed if the sample is annealed under tensile stress and the precipitate whose habit plane is more perpendicular to the stress axis is formed if the sample is annealed under compression stress.

As FIG. 5(b and c) show the orientation of Ni₄Ti₃ precipitates in the bottom Ni-rich layer change from the horizontal state in areas close to the substrate (FIG. 5b) to vertical state in areas close to the bi-layer interface (FIG. 5c). These variations in the orientation of the precipitates indicate that there is a stress gradient in the bi-layer. Also, the R-phase occurs because of the buildup of internal stresses and the depletion of Ni in the matrix. Also, the precipitates in the grain interiors of the top layer produced distorted moiréfringes, as shown in FIG. 5d. The distortion of the fringes suggests the presence of substantial local strain fields.

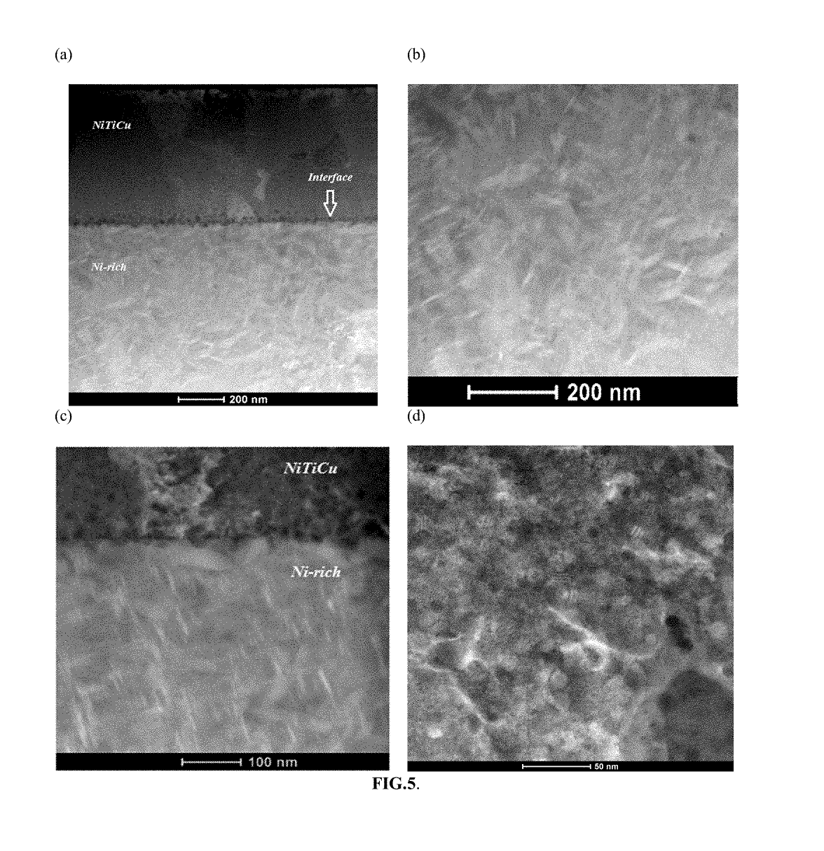

Film surface morphology was studied using tapping mode atomic force microscopy (AFM: Digital Instruments NanoScope III). AFM images of the surface morphology of the annealed bi-layer on a large scale scan (20 μm×20 μm) after annealing is shown in FIG. 6. In the bi-layers, the upper layer has martensitic structure and due to the formation of surface martensite and twinned structure, the surface roughness of the bi-layer is around 20 nm.

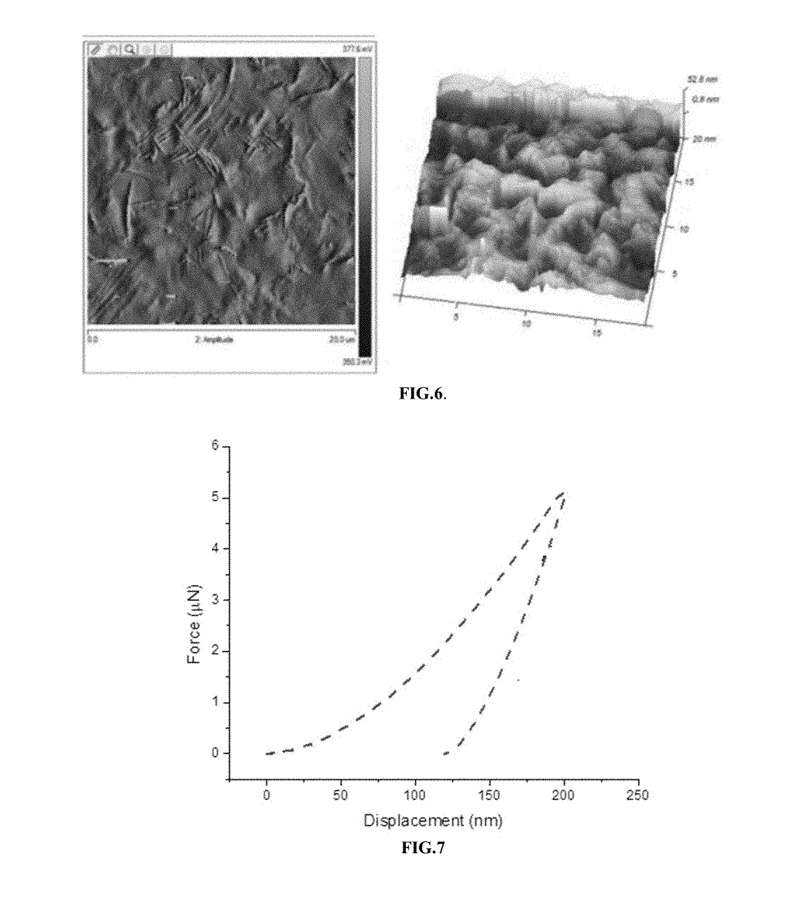

The annealed thin films were then subjected to mechanical analysis by means of nanoindentation using an Agilent G200-DCM Nanoindenter equipped with a Berkovich diamond indenter. The maximum indentation load was 10 mN. Both load and displacement were recorded during the entire loading and unloading cycle. The load-displacement experiments were repeated at five different locations on the surface of the films. The load-displacement curve of the bi-layer at maximum load 5 mN (FIG. 7) shows the low indentation depth which can be explained by the high strength of the former film. In the bi-layer, the top layer is martensitic while in the bottom layer an austenitic structure is dominant.

Furthermore, during the nanoindentation of the bi-layer film, the elastic recovery is more complex than in the single-layer thin film due to the influences of the interface between the layers and composition gradient across the film thickness. The indentation induced super elasticity effect can be characterized by the depth recovery ratio of the load-displacement curves by using the following equation:

Depth Recovery Ratio (μ)=(hₘₐₓ−hᵣ)/hₘₐₓ (1)

where hₘₐₓ is the penetration depth at the maximum load and hᵣ is the depth when the load returns to zero during unloading. Depth recovery ratios (μ) for the bi-layer is about 0.40. In order to understand the twin-rearrangement and the pseudo-elastic transformation during indentation, it is necessary to develop a theoretical picture of the process occurring under the indenter tip.

The processes occurring during indentation in the martensitic and austenitic structures can be explained by Johnson's spherical cavity model. According to this model, the deformation of the solid under the indenter tip occurs by plastic deformation in the region nearest to the tip where stresses are greatest, followed by martensite twin-rearrangement in the case of a martensitic structure or stress-induced martensitic transformation (pseudo-elasticity) in the case of austenitic structure, and finally elastic deformation in the region far from the tip.

Although these regions are not sharply specified, but by using the modified spherical cavity model, the phase transformation-elastic boundary radius can be located such that:

$$C = {\frac{d}{tan β} [ \frac{E tan β}{6 Y ( 1 - v )} + \frac{2 - 4 v}{3 - 3 v} ]}^{1 / 3} \qquad ( 2 )$$

where C is an phase transformation-elastic boundary, d is indentation depth, β is the angle between the surface and indenter (24.65° for a Berkovich indenter), E is Young's modulus (obtained from nanoindentation results, FIG. 7), Y is yield stress of the material (Y_{Martensite}=0.2 GPa (the critical stress for martensite twin-reorientation), Y_{Austenite}=0.6 GPa (the critical stress for stress-induced martensitic transformation (pseudo-elasticity)) and Y_{bi-layer}=0.4 GPa (average of the yield stresses of martensite and austenite) and v is Poisson's ratio (0.33 for NiTi alloy).

According to Eq. (2), the phase transformation-elastic boundary (C) for the bi-layer thin film is about 1.4 μm. Hence, in the bi-layer, a proportion of the phase transformation zone is located in the bottom austenitic layer and can increase the recovery ratio due to its pseudo elastic effect.

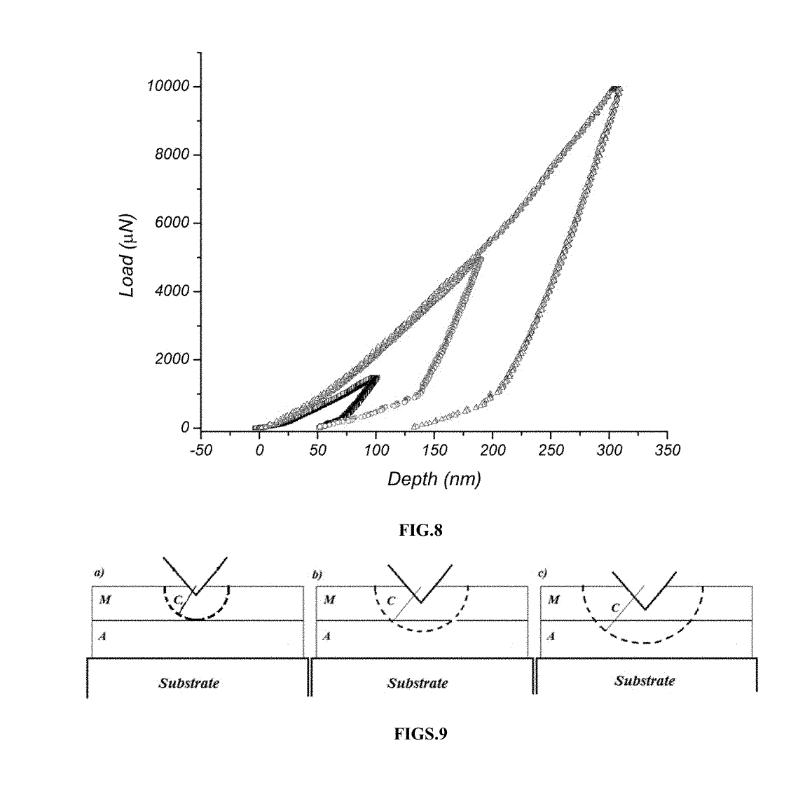

For more investigation of mechanical behavior of the bi-layer, the nanoindentation measurements were performed at different loading and are shown in FIG. 8. At low load forces (1.5 mN), the radius of phase transformation (C) is almost smaller than the upper layer thickness. Hence, it can be concluded that only the upper layer is deformed. By increasing the load up to 10 mN, the bottom layer is affected by the stress field, such that after unloading, the austenite can enhance the recovery of the bi-layer. In other words, by increasing the loading force in the bi-layer, a part of the deformation region, due to phase transformation, is located in the austenitic layer. Under these conditions, only elastic and pseudo-elastic formation can take place in the bottom layer. Thus, after unloading it can completely recover. These phenomena are schematically shown in FIG. 9.

Through the use of nanoindentation and atomic force microscopy (AFM) methods the shape memory effect is observed in the nanoscale regime. After the nanoindentation tests, the indents were scanned using an AFM and then the samples were removed and heated to above austenite finish temperature (A_{f}) and then were allowed to cool. This process transformed the martensite to the austenite which in turn the shape memory effect (SME) occurs. The films were then returned to the AFM, and the indents imaged again. The change in the depth of the remnant indentations due to the shape memory effect was quantified using NanoScope Analysis software.

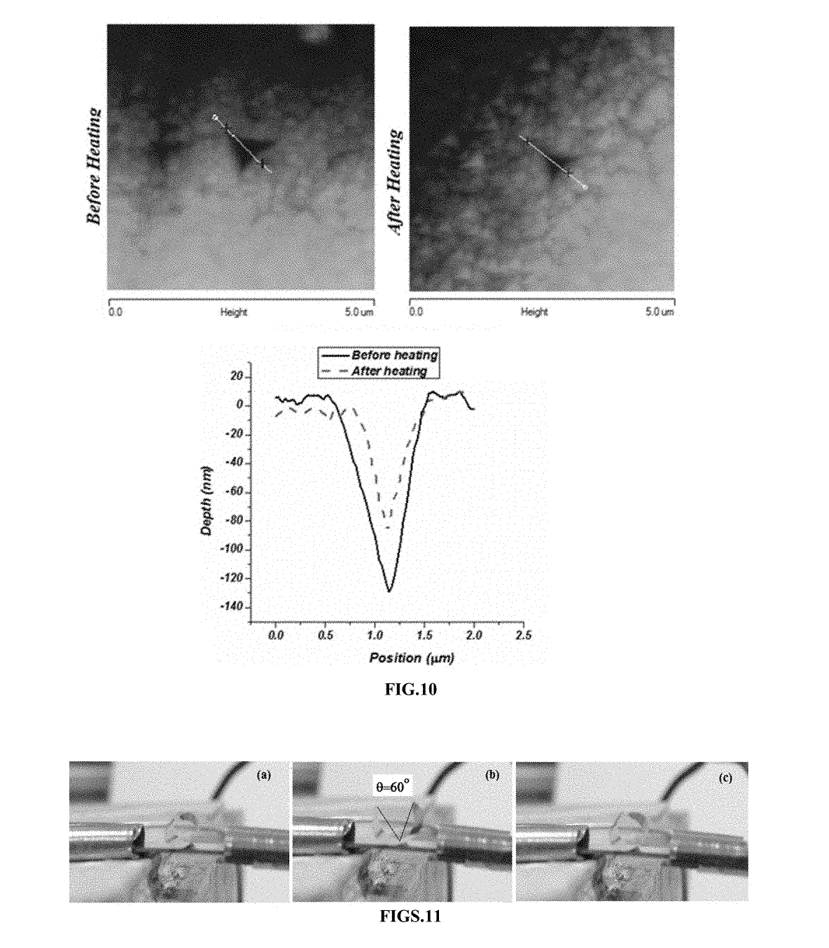

Cross section AFM scans of an indentation in the bi-layer thin film before and after heating are shown in FIG. 10. In the bi-layer after heating, the indent becomes shallow, which indicates recovery of the deformation accommodated through shape memory process. This recovery can be quantified using a recovery ratio:

$$R = \frac{{D}_{bh} - {D}_{ah}}{{D}_{bh}} \qquad ( 3 )$$

where D_{bh} and Dₐₕ are indent depth before and after heating, respectively. The insets in FIG. 10 show profiles of the indentations before and after heating which were used to determine D_{bh} and Dₐₕ, respectively. The recovery ratios (R) of the bi-layer is about 0.33.

For studying the two-way shape memory effect of the bi-layer, the free standing film was heated to above 80° C. and then cooled to room temperature. The two-way shape memory effect can be clearly observed from the photos of free standing bi-layer thin film as shown in FIG. 11. At room temperature, the film rolls due to the existence of residual stress as shown in FIG. 11(a). When heated gradually above A_{f}, it can be seen that the film is gradually unrolled as shown from FIG. 10(b), due to the shape memory effect. After cooling down to room temperature, the sample rolls again, i.e. recovering to its room temperature shape as shown in FIG. 10(c).

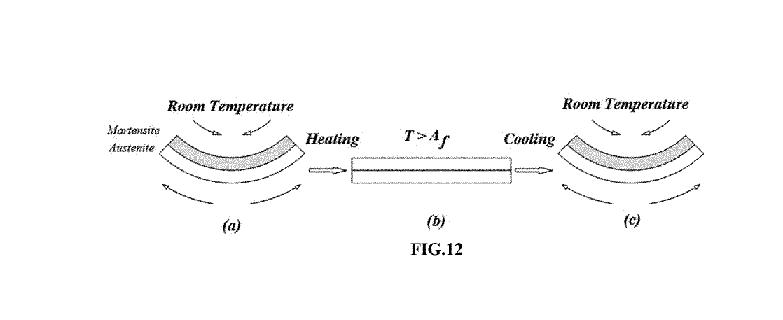

This two-way shape memory effect is not generated by the usual special thermo-mechanical training procedures of Ni—Ti thin films, and it is most likely due to the residual stress in the bi-layer thin film structure. Another possible reason is that the bi-layer thin films is not uniform across their thicknesses, but have a slight gradation in the thickness. Because of diffusion of the Cu and Ni in the bi-layer thin film after crystallization, the chemical gradient is more sensible, Mohri et al. Therefore, internal stresses and compositional gradient through the film thickness of the bi-layer lead to a high two-way shape memory recover. The two-way shape memory effect related to the residual stress is schematically shown in FIG. 12.

As the TEM results shown (FIG. 5), the orientation of precipitates indicates the existence of the tensile stress close to the substrate and compressive stress near the interface. The residual stresses that are larger than the yield stress of the martensite phase can bend a film into a rolled-shape while the bottom austenitic layer is in elastic or pseudo elastic state, but when heated the upper martensitic layer transformed to the austenite phase and can overcome the residual stress and reverts to unrolled-shape. After subsequent cooling because of the transformation austenite to the martensite in the top layer and residual stress, the bi-layer rolled again.

Maximum force output utilizing the two-way effect is dependent on the magnitude of the residual stresses. In other word the force available during recovery to the low temperature phase supplied by the residual stresses, while in heating it is the force of the shape memory effect after overcoming the opposing residual stresses. This two-way shape memory effect is quite applicable, to develop thin film micro-actuators.

1- A method for development of an intrinsic two-way shape memory thin film, comprising the steps of:
Depositing a bi-layer thin film by a DC magnetron sputtering system, using teo alloy targets on a substrate, at a predetermined temperature, and then crystallized at 500° C. for 1 h under vacuum (<10⁻⁷ mbar).

2- The method of claim 1, wherein Said bi-layer thin film is (Ni-rich/Ti-rich(NiTiCu)).

3- The method of claim 2, wherein said predetermined temperature is room temperature, and wherein said substrate is Si (111) substrate.

4- The method of claim 3, wherein said tow alloy targets were prepared using vacuum arc re-melting (VAR).

5- The method of claim 4, wherein said thin film was depostited using the following parameters:
base pressures<10⁻⁷ mbar, P_{Ar}≈3×10⁻³ mbar, target substrate distance=50 mm, power=200 W;
wherein a substrate holder was kept rotating during deposition in order to achieve a uniform distribution of composition.

6- The method of claim 5 wherein at first an Ni-rich layer was deposited onto said Si substrate with thickness of at least 1 μm and then NiTiCu were deposited onto said Ni-rich layer.

7- The method of claim 6, wherein a gradient in said chemical composition and residual stresses in said bi-layer lead to change phase transformation temperatures and exhibited small thermal hysteresis; wherein said bi-layer comprises super-elasticity effect and partial permanent strain because of composite structure; also comprising an extent of an indenter penetration recovery on unloading, due to a bottom austenitic layer which enhances the recovery of an upper martensitic layer.

8- The method of claim 7, wherein said bi-layer comprises superelastisity and shape memory effect, simultaneously.

9- The method of claim 8, wherein the existence of said gradient in said chemical composition and residual stresses in said bi-layer lead to a two-way shape memory effect intrinsically without needing complicated thermo-mechanical process with a narrow hysteresis temperature.

10- The method of claim 9, wherein said crystallization was performed at high teparture deposition and/or post annealing; where said post annealing was performed at the lowest possible annealing temperature for minimum annealing duration in order to minimize said reaction between said thin film and said substrate.
